(19) United States
(12) Patent Application Publication
(10) Pub. No.: US 2015/0311412 A1
(43) Pub. Date: Oct. 29, 2015

(54) Optical Adapter Device for Light-Emitting Diodes

(71) Applicants: Alexander POTEMKIN, Barsbuettel (DE); Petr Nikolaevich LUSKINOVICH, Moscow (RU); Vladimir Alexandrovich ZHABOTINSKIY, Moscow (RU)

(72) Inventors: Alexander POTEMKIN, Barsbuettel (DE); Petr Nikolaevich LUSKINOVICH, Moscow (RU); Vladimir Alexandrovich ZHABOTINSKIY, Moscow (RU)

(73) Assignee: Alexander Potemkin, Barsbuettel (DE)

(21) Appl. No.: 14/407,342

(22) PCT Filed: Jun. 11, 2012
(86) PCT No.: PCT/IB2012/001126

§ 371 Date: Jul. 2, 2015

(51) Int. Cl. H01L 33/58; H01L 33/04

(52) U.S. Cl. CPC H01L 33/58; H01L 33/04

(57) ABSTRACT

An optical adapter device is provided to increases the luminous efficiency of a light emitting diode without reducing service life. The optical adapter device includes a transparent material with an increased refractive index, and an additional layer between the emitting surface of the semiconductor and said optical adapter device. The additional layer is formed from a material with a lower modulus of elasticity than the light emitting diode, and has a thickness that allows the tunneling of the light emitted from the light emitting diode.

The invention relates to the field of optical adapter devices for light emitting diodes which can be used as adapter devices in the manufacture of light emitting diodes exhibiting a higher luminous efficiency. The invention can be used both for manufacturing energy saving light bulbs as well as high intensity light emitting diode floodlights.

The high refractive indices of semiconductor materials (more than 2.5 for silicon carbide and 3.3 for gallium arsenide) and the relatively low refractive indices of 1.6 for plastic materials which are used in mass production, lead to considerable reflections of the light at the interface between the semiconductor of the LED and the plastic material of the optical adapter device. The use of materials exhibiting a high refractive index, such as chalcogenide glasses, etc., for optical adapter devices is not possible in most cases, because the linear coefficients of thermal expansion are very different, a feature that gives rise to additional stresses and shortens the service life of the light emitting diode. Known are optical adapter devices on the basis of a hemisphere made of a semiconductor material, which corresponds to the semiconductor material, from which the light-generating range is manufactured, for example, the range of the infrared light emitting diode AL107A and the light emitting diode that is described in the Korean Patent No. KR101078063 HIGH EFFICIENCY LIGHT EMITTING DIODE (Oct. 31, 2011).

Known are optical adapter devices on the basis of a Weierstrass hemisphere made of the same semiconductor material, from which the light-generating range of a light emitting diode of the type 3L115 is made and also from International Patent Publication No. WO 2007/123289 A1, HIGH EFFICIENCY LED WITH MULTI-LAYER REFLECTOR STRUCTURE AND METHOD FOR FABRICATING THE SAME. In this design the coefficient of thermal expansion of the material of the light emitting diode and of the optical adapter device is the same, a feature that provides a high luminous efficiency and long service life. The drawback with this design is the manifold increase in the semiconductor consumption and the corresponding increase in the cost of the light emitting diode.

Known are optical adapter devices based on synthetic plastic materials, where the radiation, which is emitted from the semiconductor, is emitted through the dome-shaped cover to the environment from International Patent Publication No. WO 2011/002508 A2 LIGHT EMITTING DIODE LIGHT ENGINE. The drawback with this design is the low luminous efficiency due to the large difference between the refractive index of the semiconductor of the light emitting diode and the refractive index of the synthetic plastic material of the optical adapter device.

The present invention relates to a method for increasing the luminous efficiency and to the optical adapter device, which is required to implement said method, in order to meet the objective of increasing the efficiency of the conversion of the electric energy into light without reducing the service life.

The method for increasing the luminous efficiency includes introducing an additional layer between the material of the light emitting diode and an optical adapter device made of a material exhibiting a refractive index similar to that of the light emitting diode. This additional layer has a low modulus of elasticity, lower than that of the light emitting diode and the adapter device, and has a thickness that is well below the wavelength of the light, which is emitted from the light emitting diode and which allows an efficient tunneling of the light through the layer.

The device for implementing this method consists of a light emitting diode, into which a transparent additional layer, exhibiting a low modulus of elasticity, and the optical adapter device, exhibiting a refractive index similar to that of the material of the light emitting diode, are added through tunneling.

The aforementioned object of preserving the service life is achieved by the low value of the modulus of elasticity of the material of the additional layer, wherein this low modulus of elasticity reduces the mechanical stresses that are generated between the material of the light emitting diode and the optical adapter device due to the difference of the coefficient of thermal expansion. The introduction of the additional layer makes it possible to use materials for the optical adapter device that exhibit a similarly high refractive index, but a very different coefficient of thermal expansion than the material of the light emitting diode.

The object stated above is also achieved by means of the use of an additional layer exhibiting inhomogeneities that reduce the modulus of elasticity of the material.

The aforementioned object of increasing the efficiency is achieved by means of the use of an additional layer having a thickness (by a multiple less than the wavelength of the light emitted from the light emitting diode) that is transparent to the light, emitted from the light emitting diode, through tunneling.

The aforementioned object of increasing the efficiency is achieved by means of the use of an additional layer exhibiting a thickness (by a multiple less than the wavelength of the light, emitted from the light emitting diode) that is transparent to the light, emitted from the light emitting diode, through tunneling; and said additional layer is filled with nanoparticles exhibiting a refractive index that comes close to that of the material of the light emitting diode.

Other objects, advantages and novel features of the present invention will become apparent from the following detailed description of one or more preferred embodiments when considered in conjunction with the accompanying drawings.

### BRIEF DESCRIPTION OF THE DRAWINGS

FIGS. 1-3 are schematic illustrations of embodiments of optical adapter devices in accordance with the present invention.

### DETAILED DESCRIPTION

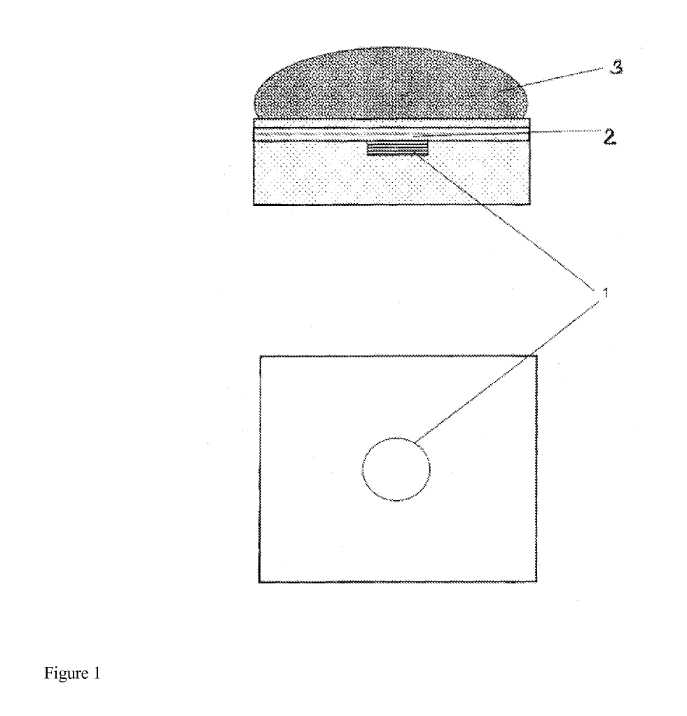

The principle of the proposed method and the device, which is required for the implementation of said method, can be explained by means of the practical example and FIG. 1, which shows in schematic form the principle (in a sectional view and plan view).

The optical adapter device includes the spherical optical element 1, made of a material exhibiting a refractive index similar to that of the material of the light emitting diode, and the additional layer 2 exhibiting a low modulus of elasticity. In this case the additional layer is affixed between the spherical adapter element and the radiating surface of the light emitting diode.

The technology for producing such a device is based on hybrid microelectronics technologies and includes first applying the additional layer and thereafter the optical adapter device on the optical surface.

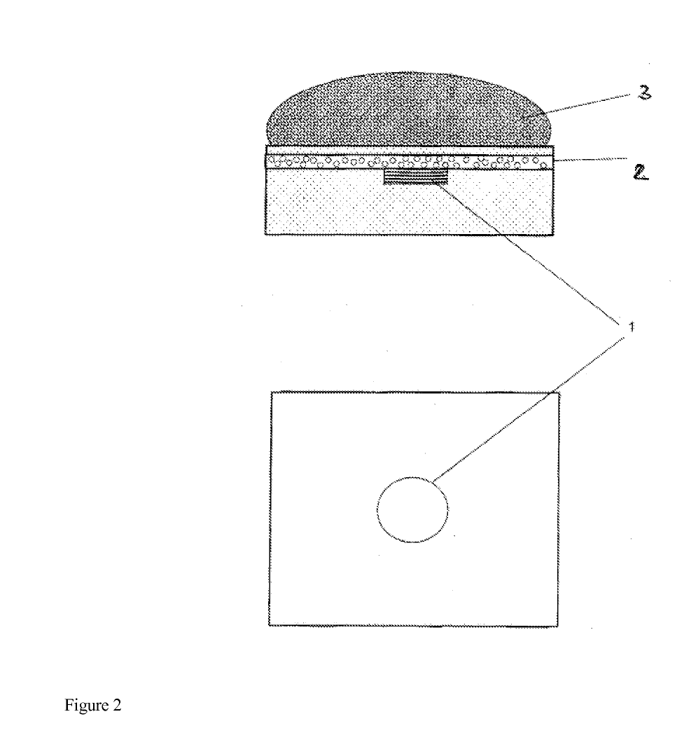

It is permissible to use an additional layer 2, which contains nanoparticles exhibiting a refractive index similar to that of the material 3 of the light emitting diode (FIG. 2).

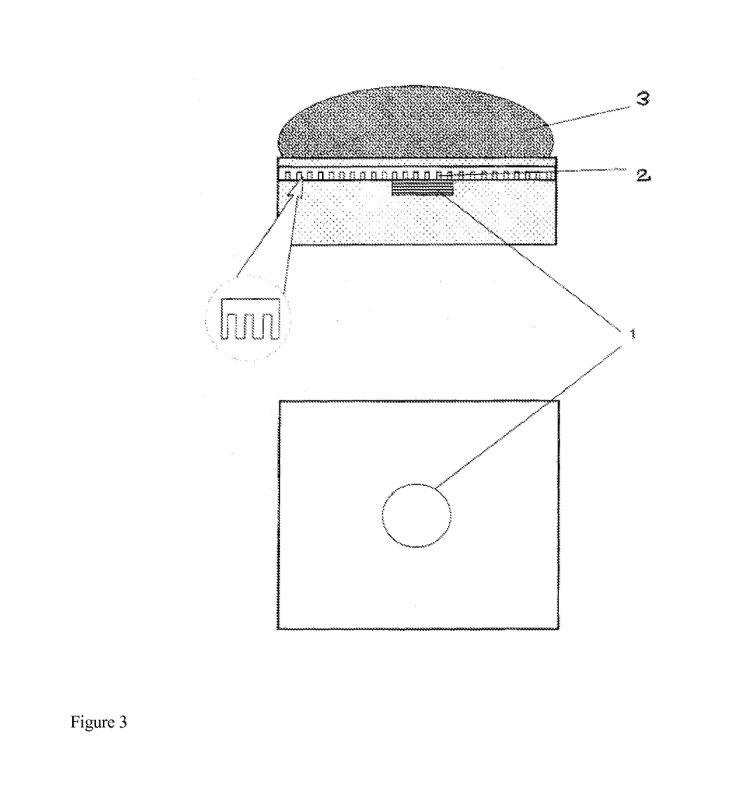

It is also permissible to use an additional layer 2, which is made of the material of the optical adapter device or the material of the surface of the light emitting diode and contains voids, in order to reduce the transverse rigidity of the material (FIG. 3).

In this way both the method, which is presented herein and which is intended for increasing the efficiency of the optical adapter device, and the device, which is manufactured on the basis of this principle, ensure that the luminous efficiency of the active surface area of the light emitting diode will be increased without reducing the service life.

The foregoing disclosure has been set forth merely to illustrate the invention and is not intended to be limiting. Since modifications of the disclosed embodiments incorporating the spirit and substance of the invention may occur to persons skilled in the art, the invention should be construed to include everything within the scope of the appended claims and equivalents thereof.

1-4. (canceled)

5. An optical adapter device for a light emitting, the light emitting diode being formed from a semiconductor material and having a radiating surface for emitting light, a first optical refractive index and a first modulus of elasticity, comprising:
an optical adapter element configured to be placed adjacent to the radiating surface of the light emitting diode; and
an additional layer disposed between the optical adapter element and the radiating surface of the light emitting diode,
wherein
the optical adaptor has a second optical refractive index similar to the first optical refractive index of the material of the light emitting diode and a thickness less than a wavelength of light radiated from the light emitting diode, and
the additional layer has a second modulus of elasticity that is lower than the first modulus of elasticity of the material of the light emitting diode.

6. The optical adapter device as claimed in claim 5, wherein
the additional layer comprises nanoparticles having a size that is smaller than the wavelength of the light radiated from the light emitting diode and a third optical refractive index that is higher than a fourth optical refractive index of the additional layer.

7. The optical adapter device as claimed in claim 5, wherein
the additional layer is connected to at least one of the adapter device and the radiating surface of the light emitting diode, and
the additional layer is formed from a material having nano and micro voids.

8. The optical adapter device as claimed in claim 5, wherein
the optical adaptor device has a fifth refractive index similar to that of the semiconductor material of the light emitting diode.

9. The optical adapter device as claimed in claim 6, wherein
the optical adaptor device has a fifth refractive index similar to that of the semiconductor material of the light emitting diode.
